(19) United States
(12) Patent Application Publication
(10) Pub. No.: US 2026/0082898 A1
(43) Pub. Date: Mar. 19, 2026

(54) BACKEND OPTICAL INTERCONNECTS

(71) Applicants: Abhishek A. Sharma, Portland, OR (US); Wilfred Gomes, Portland, OR (US); Tahir Ghani, Portland, OR (US)

(72) Inventors: Abhishek A. Sharma, Portland, OR (US); Wilfred Gomes, Portland, OR (US); Tahir Ghani, Portland, OR (US)

(21) Appl. No.: 18/888,255

(22) Filed: Sep. 18, 2024

(51) Int. Cl. H01L 23/528; G02B 6/13; H01L 21/768

(52) U.S. Cl. CPC H10W 20/435; G02B 6/13; H10W 20/01

(57) ABSTRACT

Backend optical interconnects may be formed in backend of line (BEOL) layers together with conductive interconnects, and may enable high data-rate communication in a dense and cost-effective manner. In one example, backend optical interconnects can be formed using existing structures in the process (e.g., vias and lines). For example, an IC structure may include an interconnect layer over a device region, where the interconnect layer includes both conductive interconnects and optical interconnects (e.g., wave guides). The optical interconnect includes a core material (e.g., a dielectric material) and may be parallel to metal lines or may be a via that is orthogonal to metal lines in the interconnect layer.

### BACKGROUND

For the past several decades, the scaling of features in integrated circuits (ICs) has been a driving force behind an ever-growing semiconductor industry. Scaling to smaller and smaller features enables increased densities of functional units on the limited real estate of semiconductor chips. For example, shrinking transistor size allows for the incorporation of an increased number of memory or logic devices on a chip, lending to the fabrication of products with increased capacity. The drive for the ever-increasing capacity, however, is not without issue. The necessity to optimize fabrication and performance of each component is becoming increasingly significant.

### BRIEF DESCRIPTION OF THE DRAWINGS

Embodiments will be readily understood by the following detailed description in conjunction with the accompanying drawings. To facilitate this description, like reference numerals designate like structural elements.

Embodiments are illustrated by way of example, and not by way of limitation, in the figures of the accompanying drawings.

FIG. 1 is a cross-sectional side views of an integrated circuit (IC) structure including backend optical interconnects, in accordance with various embodiments.

FIGS. 2A-2B are block diagrams of optical receiver and optical transmitter circuits that may be included in an IC structure with backend optical interconnects, in accordance with examples described herein.

FIGS. 3-7 are cross-sectional side views of examples of backend optical interconnects, in accordance with embodiments disclosed herein.

FIGS. 8A-8B, 9A-9B, and 10A-10B are different cross-sectional views of examples of backend optical interconnects, in accordance with embodiments disclosed herein.

FIGS. 11A-11H illustrate cross-sectional views of IC structures including optical interconnects, in accordance with various embodiments.

FIG. 12 is a flow diagram of an example method for fabricating an IC structure including backend optical interconnects, in accordance with some embodiments.

FIGS. 13A-13E provide cross-sectional side views at various stages in the fabrication of an example IC structure according to the method of FIG. 12, in accordance with some embodiments.

FIG. 14 is a flow diagram of an example method for fabricating an IC structure including backend optical interconnects, in accordance with some embodiments.

FIGS. 15A-15E provide cross-sectional side views at various stages in the fabrication of an example IC structure according to the method of FIG. 14, in accordance with some embodiments.

FIG. 16 is a top view of a wafer and dies that may include any of the IC structures disclosed herein, in accordance with any of the embodiments disclosed herein.

FIG. 17 is a side, cross-sectional view of an IC package that may include any of the IC structures disclosed herein, in accordance with various embodiments.

FIG. 18 is a side, cross-sectional view of an IC device assembly that may include any of the IC structures disclosed herein, in accordance with any of the embodiments disclosed herein.

FIG. 19 is a block diagram of an example electrical device that may include any of the IC structures disclosed herein, in accordance with any of the embodiments disclosed herein.

### DETAILED DESCRIPTION

Disclosed herein are integrated circuit (IC) structures including backend optical interconnects.

Optical interconnects, such as waveguides are structures that guide electromagnetic waves along a specific path. Traditional waveguides may provide low loss and high power handling capabilities, but are typically formed as external components (e.g., cables, etc.) that interface with other parts of the system through transitions or connectors. Substrate Integrated Waveguides (SIWs) integrate waveguide-like structures directly into planar circuit boards. However, there are also limitations in the use of SIWs. For example, SIWs are typically formed in the substrate of a circuit board (e.g., the substrate of a package substrate or motherboard), may also be limited in terms of the substrates that they can be implemented in (e.g., single crystal substrates), and are generally not implemented together in the same area with other integrated circuits. Furthermore, challenges exist in implementing SIWs for sub-millimeter-wave signaling. For example, terahertz-compatible optical interconnects may suffer from excessive thermal noise interference.

In contrast, in accordance with examples herein, backend optical interconnects may be formed in backend of line (BEOL) layers together with conductive interconnects to enable high data-rate communication in a dense and cost-effective manner. In one example, backend optical interconnects can be formed using existing structures in the process (e.g., vias and lines). For example, an IC structure may include an interconnect layer over a device region, where the interconnect layer includes both conductive interconnects and optical interconnects (e.g., wave guides). The optical interconnect includes a core material (e.g., a dielectric material) and may be parallel to metal lines or may be a via that is orthogonal to metal lines in the interconnect layer. In one example, the IC structure includes a material including a metal around one or more sides of the optical interconnect (or on sidewalls of the optical interconnect) to provide shielding.

IC structures including backend optical interconnects as described herein may be implemented in one or more components associated with an IC or/and between various such components. In various embodiments, components associated with an IC include, for example, transistors, diodes, power sources, resistors, capacitors, inductors, sensors, transceivers, receivers, antennas, etc. Components associated with an IC may include those that are mounted on IC or those connected to an IC. The IC may be either analog or digital and may be used in a number of applications, such as microprocessors, optoelectronics, logic blocks, audio amplifiers, etc., depending on the components associated with the IC. In some embodiments, IC structures as described herein may be included in a radio frequency IC (RFIC), which may, e.g., be included in any component associated with an IC of an RF receiver, an RF transmitter, or an RF transceiver, e.g., as used in telecommunications within base stations (BS) or user equipment (UE). Such components may include, but are not limited to, power amplifiers, low-noise amplifiers, RF filters (including arrays of RF filters, or RF filter banks), switches, upconverters, downconverters, and duplexers. In some embodiments, IC structures as described herein may be included in memory devices or circuits. In some embodiments, IC structures as described herein may be employed as part of a chipset for executing one or more related functions in a computer.

For purposes of explanation, specific numbers, materials and configurations are set forth in order to provide a thorough understanding of the illustrative implementations. However, it will be apparent to one skilled in the art that the present disclosure may be practiced without the specific details or/and that the present disclosure may be practiced with only some of the described aspects. In other instances, well-known features are omitted or simplified in order not to obscure the illustrative implementations. The terms “substantially,” “close,” “approximately,” “near,” and “about,” generally refer to being within +/−10% of a target value, e.g., within +/−5% of a target value, based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−10% of a target value, e.g., within +/−5% of a target value, based on the context of a particular value as described herein or as known in the art.

In the following description, references are made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense.

In the drawings, while some schematic illustrations of example structures of various devices and assemblies described herein may be shown with precise right angles and straight lines, this is simply for ease of illustration, and embodiments of these assemblies may be curved, rounded, or otherwise irregularly shaped as dictated by, and sometimes inevitable due to, the fabricating processes used to fabricate semiconductor device assemblies.

Therefore, it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication. Inspection of layout and mask data and reverse engineering of parts of a device to reconstruct the circuit using e.g., optical microscopy, TEM, or SEM, and/or inspection of a cross-section of a device to detect the shape and the location of various device elements described herein using, e.g., Physical Failure Analysis (PFA) would allow determination of presence of IC structures including backend optical interconnects as described herein.

Various operations may be described as multiple discrete actions or operations in turn, in a manner that is most helpful in understanding the claimed subject matter. However, the order of description should not be construed as to imply that these operations are necessarily order dependent. These operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges.

The description uses the phrases “in an embodiment” or “in embodiments,” which may each refer to one or more of the same or different embodiments. The terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner. Although some materials may be described in singular form, such materials may include a plurality of materials, e.g., a semiconductor material may include two or more different semiconductor materials.

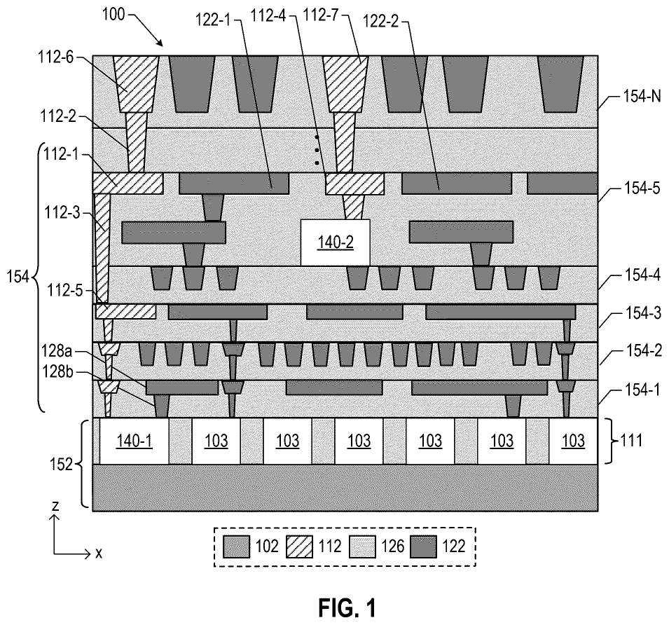

A number of elements referred to in the description of FIGS. 1, 3-7, 8A-8B, 9A-9B, 10A-10B, 11A-11H, 13A-13E, and 15A-15E with reference numerals are illustrated in these drawings with different patterns, with a legend showing the correspondence between the reference numerals and patterns being provided at the bottom of each drawing page containing FIGS. 1, 3-7, 8A-8B, 9A-9B, 10A-10B, 11A-11H, 13A-13E, and 15A-15E. For example, the legend illustrates that FIG. 1 uses different patterns to show a substrate 102, a conductive interconnect 122, and so on.

FIG. 1 is a cross-sectional side view of an IC structure 100 including backend optical interconnects, in accordance with various embodiments. The IC structure 100 includes front-end of line (FEOL) layers 152 and BEOL layers 154. A FEOL layer refers to a layer formed in the FEOL, such as a device layer or device region. In the FEOL, individual semiconductor devices components (e.g., transistors, capacitors, resistors, etc.) can be patterned in a wafer. A BEOL layer refers to a layer formed in the BEOL, such as an interconnect layer (e.g., metal layer) of a metallization stack. In the BEOL, interconnect structures such as conductive lines and conductive vias, separated as needed by an insulator material, can be formed to interconnect individual components. The BEOL usually starts with forming the first metal layer on the wafer. The first metal layer is often called M0. Additional metal layers can be formed on top of M0, and these metal layers are often called M1, M2, and so on.

In the example illustrated in FIG. 1, the FEOL layer 152 includes a device region 111 over a substrate 102. The substrate 102 may be a semiconductor substrate composed of semiconductor material systems including, for example, N-type or P-type materials systems. In one implementation, the semiconductor substrate may be a crystalline substrate formed using a bulk silicon or a silicon-on-insulator (SOI) substructure. In other implementations, the semiconductor substrate may be formed using alternate materials, which may or may not be combined with silicon, that include, but are not limited to, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of group III-V materials (i.e., materials from groups III and V of the periodic system of elements), group II-VI (i.e., materials from groups II and IV of the periodic system of elements), or group IV materials (i.e., materials from group IV of the periodic system of elements). In some embodiments, the substrate may be non-crystalline.

The device region 111 includes a plurality of devices 103. The devices 103 may be frontend devices (e.g., frontend transistors such as FinFETs, nanowire transistors, nanoribbon transistors, frontend memory cells, and/or other frontend devices). The devices 103 may include transistors of any architecture, such as any non-planar or planar architecture. Non-planar transistors such as double-gate transistors, tri-gate transistors, FinFETs, and nanowire/nanoribbon/nanosheet transistors refer to transistors having a non-planar architecture. In comparison to a planar architecture where the transistor channel has only one confinement surface, a non-planar architecture is any type of architecture where the transistor channel has more than one confinement surface. A confinement surface refers to a particular orientation of the channel surface that is confined by the gate field. Non-planar transistors potentially improve performance relative to transistors having a planar architecture, such as single-gate transistors. Nanoribbon transistors may be particularly advantageous for continued scaling of complementary metal-oxide-semiconductor (CMOS) technology nodes due to the potential to form gates on all four sides of a channel material (hence, such transistors are sometimes referred to as “gate all around” transistors).

The BEOL layers 154 may include a plurality of backend interconnects electrically coupled to (e.g., in electrically conductive contact with at least portions of) one or more of the plurality of FEOL devices of the FEOL layer 152. Various BEOL interconnect layers 154 may be/include one or more metal layers of a metallization stack of the IC device. Various metal layers of the BEOL interconnect layers 154 may be used to interconnect the various inputs and outputs of the devices (e.g., logic devices) in the FEOL layer 152. In one example, each of the BEOL interconnect layers 154 may include conductive interconnects 122, such as conductive vias and conductive lines/trenches. For example, the BEOL interconnect layer 154-1 includes a via portion 128b and a line or trench/interconnect portion 128a. The trench portion 128a of a metal layer is configured for transferring signals and power along electrically conductive (e.g., metal) lines (also sometimes referred to as “trenches”) extending in the x-y plane (e.g., in the x or y directions), while the via portion 128b of a metal layer is configured for transferring signals and power through electrically conductive vias extending in the z-direction, e.g., to any of the adjacent metal layers above or below. Accordingly, in one example, vias connect metal structures (e.g., metal lines or vias) from one metal layer to metal structures of an adjacent metal layer. While referred to as “metal” layers, various layers of the BEOL interconnect layers 154 may include only certain patterns of conductive metals, e.g., copper (Cu), aluminum (Al), tungsten (W), or cobalt (Co), or metal alloys, or more generally, patterns of an electrically conductive material, formed in an insulating medium such as an interlayer dielectric (ILD) 126. Although the conductive interconnects are shown with the same shading, different conductive interconnects in different layers may be formed from different conductive materials. The insulating medium may include any suitable ILD materials such as silicon oxide, carbon-doped silicon oxide, silicon carbide, silicon nitride, aluminum oxide, and/or silicon oxynitride. In some embodiments, the ILD 126 disposed between the interconnect structures in different ones of the interconnect layers may have different compositions; in other embodiments, the composition of the ILD 126 between different interconnect layers may be the same. The example illustrated in FIG. 1 includes N interconnect layers (of which 154-1, 154-2, 154-3, 154-4, 145-5, and 154-N are shown), where N is a positive integer that is greater than 1. IC structures may include fewer or more interconnect layers than those shown in FIG. 1.

In the example illustrated in FIG. 1, the IC structure 100 includes backend optical interconnects 112 in one or more of the BEOL layers 154. An optical interconnect may be or include, for example, a waveguide or wave confinement structure. The optical interconnect includes a dielectric material (e.g., a core material for transmission of optical signals), and may further include a material including a metal around the dielectric material. An optical interconnect may be considered a “backend optical interconnect” due to its location in a BEOL layer. In one example, the backend optical interconnects are in an interconnect layer that includes metal lines having a pitch that is at least around 250 nanometers (e.g., greater than or equal to about 250 nanometers, or in a range of about 250 to 4000 nanometers); however, in other examples, conductive interconnects may be present in interconnect layers with pitches that are smaller than 250 nanometers or greater than 4000 nanometers. In some examples, the backend optical interconnects may be in higher up metal layers (e.g., M10, M11, M12, M13, M14, M15, GM0, GM1, etc., where “MX” represents the (X+1)th metal layer over the frontend device region 111, and “GMX” represents the (X+1)th global or giant metal layer). In some examples, the optical interconnects 112 are coplanar with conductive interconnects. For example, the optical interconnect 112-4 is coplanar with and between conductive interconnects 122-1 and 122-2 (e.g., the optical interconnect 112-4 is in a plane with the conductive interconnects 122-1 and 122-2, where the plane is substantially parallel to the substrate 102 and device region 111, and parallel to the x-y plane as shown in FIG. 1, where the y-axis is going into and coming out of the plane).

The optical interconnects 112 may include optical vias that extend through and between layers (e.g., substantially orthogonal to the substrate 102 and device region 111) and optical lines that extend along one layer (e.g., substantially parallel to the substrate 102 and device region 111, and substantially parallel to the metal lines in that layer). For example, the optical interconnect 112-1 is substantially parallel to the conductive interconnect 122-1. In one such example, the optical interconnects 112 that are parallel to metal lines may have a thickness and/or width that are about the same as the metal lines in the same layer. For example, the optical interconnect 112-1 may have about the same thickness and/or width as the conductive interconnect 122-1, where the thickness is a dimension of the optical interconnect 112-1 in a plane substantially orthogonal to the substrate 102 (e.g., along the z-axis), and the width is a dimension of the optical interconnect 112-1 in a plane substantially parallel to the substrate 102 (e.g., along the y-axis). In one example in which there are multiple adjacent optical interconnects in a layer, the optical interconnects may have about the same pitch as conductive interconnects in the same layer. The optical interconnects 112 may also be or include optical vias, such as the optical interconnects 112-1 and 112-4. An optical via may extend between and coupled with other optical structures in interconnect layers above and below the optical via. For example, the optical interconnect 112-3 extends through the layers 154-4 and 154-5, and is coupled with and between the optical interconnects 112-1 and 112-5. The optical interconnects may be coupled with an optical receiver and/or transmitter in the IC structure 100. For example, the optical interconnects 112-1, 112-2, 112-3 and 112-5 are coupled with optical circuitry 140-1, which may include one or both of transmitter and receiver circuitry. The optical interconnect 112-4 is coupled with optical circuitry 140-2. Optical circuitry may be located in a FEOL layer or a BEOL layer. For example, the optical circuitry 140-1 is in the device region 111, and the optical circuitry 140-2 is in an interconnect layer 154-5. In some examples, an optical interconnect may be between optical circuitry of the IC structure 100 and an optical contact structure for coupling with other optical circuitry external to the IC structure 100. For example, the optical interconnect 112-4 is between the optical circuitry 140-2 and an optical interconnect 112-7, which may coupled with an external optical interconnect. Similarly, the optical interconnect 112-2 is between the optical circuitry 140-1 and an optical interconnect 112-6, which may coupled with an external optical interconnect.

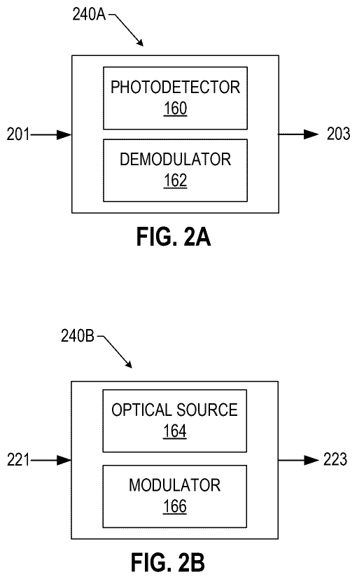

FIGS. 2A and 2B are block diagrams of optical circuitry. FIG. 2A illustrates an optical receiver 240A and FIG. 2B illustrates an optical transmitter 240B. In some examples, optical circuitry may include both receiver and transmitter circuitry (e.g., an optical transceiver). The optical receiver 240A receives an optical signal 201 from an optical interconnect (e.g., one of the optical interconnects 112 of FIG. 1), which is detected with a photodetector 160 and demodulated with a demodulator 162 and output as an electrical signal 203. The optical receiver 240A outputs an electrical signal to a conductive interconnect (e.g., one of the conductive interconnects 122 of FIG. 1). The transmitter 240B receives an electrical signal 221 and generates and outputs an optical signal 223 with an optical source 164 and modulator 166. Optical receiver and transmitter circuitry may include additional circuitry (e.g., control circuitry, filters, amplifiers, etc.).

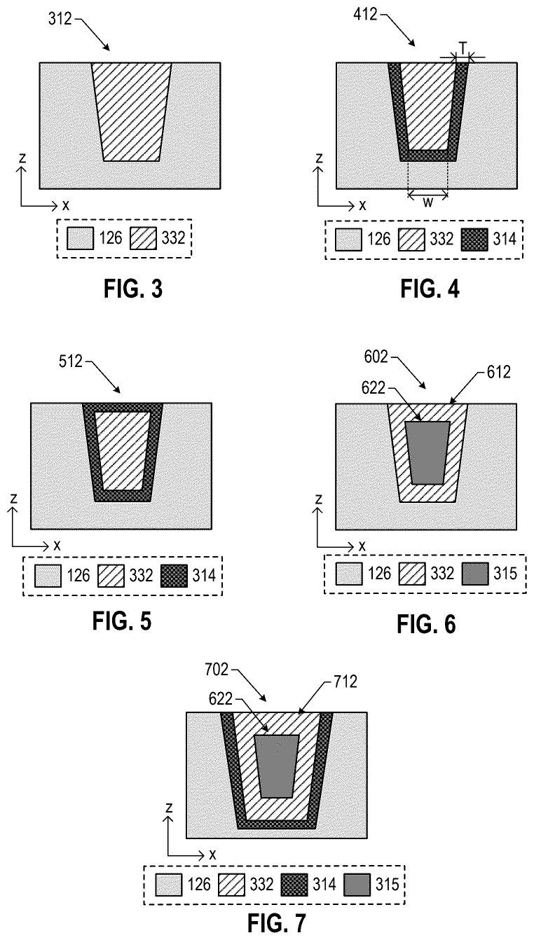

FIGS. 3-7 illustrate cross-sectional side views of examples of optical interconnects. FIGS. 3-7 illustrate optical interconnects that may be parallel to the device region (e.g., optical lines) that extend along the x-y axes shown in FIGS. 3-7, where the y-axis is going into and coming out of the page. FIG. 3 illustrates an example of an optical interconnect 312 that includes a dielectric material 332 as a core material or transmission material. The dielectric material 332 may be compatible with transmitting terahertz signals (e.g., signals in the frequency range of about 100 GHz to 10 THz, or greater than 10 THz). Terahertz signals may include signals having wavelengths in a range of about 3 millimeters to 30 micrometers, and in some examples, may be referred to as sub-millimeter-wave signals. In the example illustrated in FIG. 3, the dielectric material 332 differs from the surrounding ILD 126 in the interconnect layer in which the optical interconnect 312 is disposed. In some examples, the dielectric material 332 includes one or more of aluminum nitride, silicon carbide, aluminum scandium nitride, aluminum silicon nitride, lithium niobate, and/or other materials suitable as an optical medium. The dielectric material 332 may have particular properties that make it suitable for transmitting optical signals. For example, the dielectric material 332 has a refractive index that is greater than the ILD 126. In one example, the refractive index of the dielectric material 332 is about 10-40% greater, about 15-35% greater, or about 25-30% greater than the refractive index of the ILD 126. In the example illustrated in FIG. 3, there is not additional metal shielding material around the dielectric material 332. Therefore, there is a continuous portion of the dielectric material 332 between portions of the ILD 126, and the dielectric material 332 is in contact with (e.g., in direct contact with) the ILD 126.

FIG. 4 illustrates another example of an optical interconnect 412 that includes a shielding material 314 around three sides of the optical interconnect 412. In the example illustrated in FIG. 4, the shielding material 314 is over or on sidewalls of the optical interconnect 412 (e.g., on sidewalls of the opening in which the optical interconnect 412 is formed) and over or on a bottom of the optical interconnect 412 (e.g., on the bottom of the opening in which the optical interconnect 412 is formed). In some examples, the shielding material may also act as a cladding material, which can prevent leakage and confine light within the optical interconnect 412. In some examples, the shielding material 314 is a material that includes a metal. In some examples, the shielding material 314 includes one or more of tantalum nitride, titanium nitride, tungsten, ruthenium, molybdenum, copper, and titanium tantalum. In some examples, the shielding material 314 includes or is the same material as conductive interconnects in the same layer as the optical interconnect. For example, the shielding material 314 and adjacent conductive interconnects may be or include tungsten. In other examples, the shielding material 314 includes a different material than conductive interconnects in the same layer as the optical interconnect. For example, adjacent conductive interconnects may be or include copper, and the shielding material may include a metal other than copper (e.g., tungsten, ruthenium, etc.). In some examples, the thickness of the shielding material 314 is in a range of about 1-30% of a width of the optical interconnect, or in a range of about 5-25% of the width of the optical interconnect (e.g., where the thickness T of the shielding material 314 on the sidewalls is a dimension of the shielding material 314 in a plane substantially parallel to the device region, the width W of the dielectric material 332 is a dimension of the dielectric material 332 in the plane). In the example illustrated n FIG. 4, the thickness of the shielding material 314 at the bottom of the optical interconnect 412 is about the same as on the sidewalls of the optical interconnect 412 (e.g., the thickness of the shielding material 314 on the bottom of the optical interconnect 412 is about T). Thus, FIG. 4 illustrates an example in which the dielectric material 332 of the optical interconnect 412 is lined with a shielding material 314 on three sides (e.g., sides and bottom).

FIG. 5 illustrates another example of an optical interconnect 512 that includes the shielding material 314 around four sides of the optical interconnect 512. Thus, in addition to lining the sidewalls and bottom of the dielectric material 332, the shielding material 314 is also over the top of the dielectric material 332. Therefore, in the example illustrated in FIG. 5, the shielding material 314 surrounds (e.g., completely surrounds) at least a portion of the dielectric material 332. For example, in a cross-sectional view such as shown in FIG. 5, the dielectric material 332 is surrounded by shielding material 314.

FIGS. 6 and 7 illustrate examples of optical interconnects 612 and 712 that include a conductive core in the dielectric material 332. For example, turning first to FIG. 6, the optical interconnect 612 includes the dielectric material 332 that is the optical medium and a conductive material 315 in and surrounded by the dielectric material 332. The conductive material 315 may be, for example, a conductive interconnect within or encapsulated by the optical interconnect. For example, the IC structure 602 in FIG. 6 may include an optical interconnect 612 around a conductive interconnect 622. In the example illustrated in FIG. 6, the optical interconnect 612 is going into and coming out of the page (e.g., the optical interconnect 612 is an optical line extending along the y-axis, where the y-axis is going into and coming out of the page), and the conductive interconnect 622 is a conductive line that is substantially parallel to and within the optical line).

The conductive material 315 may include any of the conductive interconnect materials mentioned above, or any other suitable electrically conductive material. In one such example, the ratio of the volume of the conductive material 315 to the volume of dielectric material 332 of the IC structure 602 (e.g., the combined optical interconnect 612 and conductive interconnect 622) may be in a range of about 10-80%, about 20-70%, or about 40-60%. In other words, the ratio of the cross-sectional area of the conductive material 315 to the cross-sectional area of the dielectric material 332 (e.g., along a plane substantially orthogonal to the substrate and orthogonal to the length of the interconnects 612, 622) is in a range of about 10-80%, about 20-70%, or about 40-60%. FIG. 7 also illustrates an example of an IC structure 702 that includes a conductive interconnect 622 within an optical interconnect 712. The optical interconnect 712 of FIG. 7 differs from the optical interconnect 612 of FIG. 6 in that it is lined by a shielding material 314 on three sides. In one example, the shielding material may also be present over the dielectric material 332 of the optical interconnect 712. Therefore, in the example in FIG. 7, the dielectric material 332 is between the shielding material 314 and the conductive material 315. Thus, FIGS. 6 and 7 illustrate examples in which an IC structure may include an optical interconnect with an electrical/conductive interconnect in parallel in the same interconnect path.

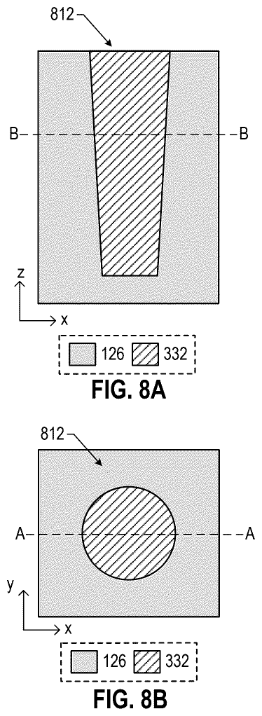

FIGS. 8A-8B, 9A-9B, and 10A-10B are different cross-sectional views of examples of backend optical interconnects. In contrast to FIGS. 3-7, which illustrate optical interconnects that may be parallel to the device region (e.g., optical lines), FIGS. 8A-8B, 9A-9B, and 10A-10B illustrate optical interconnects that are orthogonal to the substrate (e.g., optical vias). Those figures of FIGS. 8A-8B, 9A-9B, and 10A-10B that are labeled with a letter A (e.g., FIG. 8A) illustrate cross-sections in the x-z plane of the example coordinate system shown in FIG. 1 along a plane AA shown in a corresponding figure labeled with a letter B (e.g., along a plane AA shown in FIG. 8B). Those figures of FIGS. 8A-8B, 9A-9B, and 10A-10B that are labeled with a letter B (e.g., FIG. 8B) illustrate cross-sections in the x-y plane of the example coordinate system shown in FIG. 1 along a plane BB shown in a corresponding figure labeled with a letter A (e.g., along a plane BB shown in FIG. 8A).

Turning first to FIGS. 8A-8B, the optical interconnect 812 includes a dielectric material 332 as an optical medium in an ILD 126. The optical interconnect 812 in FIGS. 8A and 8B is an optical via (e.g., a via opening filled with a suitable dielectric material 332) for transmitting signals between two layers (e.g., between two BEOL layers). In some examples, the optical interconnect 812 may have a tapered shape with a wider top portion and a narrower bottom portion (where the width of the optical interconnect 812 is a dimension of the optical interconnect 812 in a plane substantially parallel with the substrate, e.g., along the x-axis as shown in FIGS. 8A and 8B). In the example illustrated in FIG. 8B, the optical interconnect 812 has a round (e.g., substantially circular) cross-section along the x-y plane. The optical interconnect 812 may have dimensions similar to conductive vias of the IC structure.

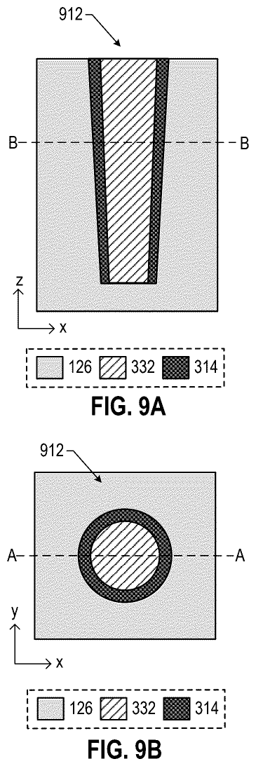

FIGS. 9A-9B illustrate another example of an optical interconnect 912. The optical interconnect 912 is similar to the optical interconnect 812 of FIGS. 8A and 8B in that it includes a via filled with a dielectric material 332 that extends through one or more interconnect layers. The optical interconnect 912 of FIGS. 9A and 9B differs from the optical interconnect 812 in that a shielding material 314 is present on sidewalls of the optical interconnect 912. The thickness of the shielding material 314 on the sidewalls of the optical interconnect 912 may be similar to the example described above with respect to FIG. 4 (e.g., the shielding material 314 on the sidewalls of the optical interconnect 912 may have the thickness T). In the example illustrated in FIG. 9A, the shielding material is absent from a bottom and top of the optical interconnect 912 to enable coupling the optical interconnect 912 with optical interconnects in layers below and above the optical interconnect 912.

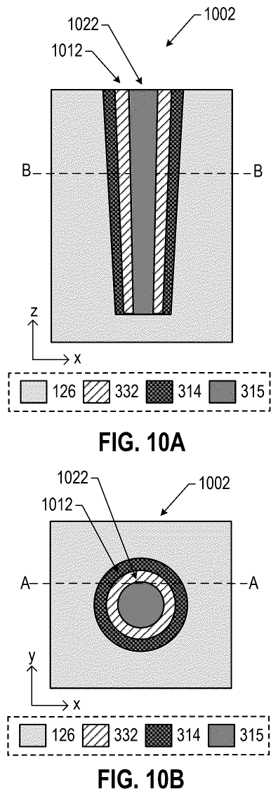

FIGS. 10A-10B illustrate another example of an optical interconnect 1012. The optical interconnect 1012 is similar to the optical interconnect 912 of FIGS. 9A and 9B in that it includes a via filled with a dielectric material 332 that extends through one or more interconnect layers. The IC structure 1002 illustrated in FIGS. 10A and 10B further includes a conductive via 1022 (e.g., a conductive material 315) surrounded by the dielectric material 332 of the optical interconnect 1012. The percentage of the conductive material 315 relative to the dielectric material 332 in the via opening may be similar to the examples discussed above with respect to FIGS. 6 and 7. Thus, FIGS. 8A-8B, 9A-9B, and 10A-10B illustrate examples of optical interconnects that extend between layers, and which couple to optical structures in those layers.

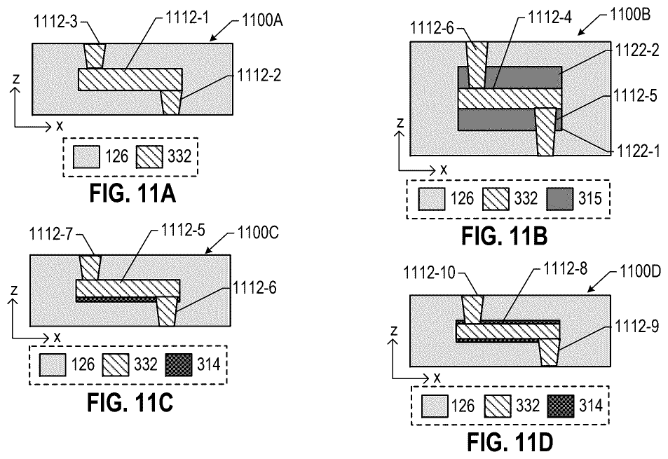

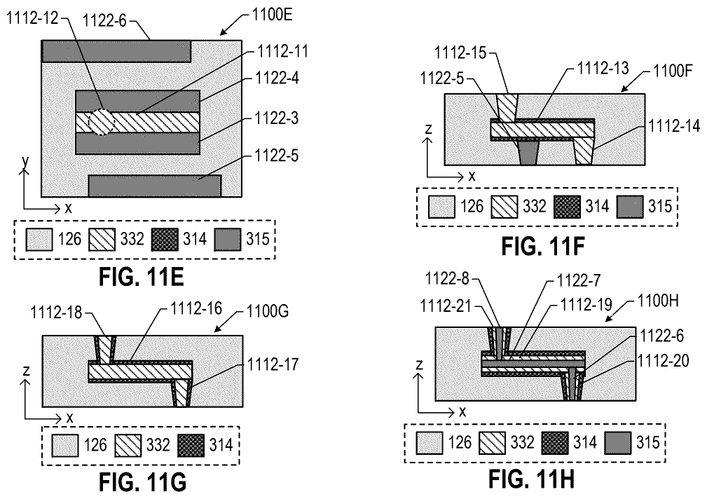

FIGS. 11A-11H illustrate cross-sectional views of IC structures including optical interconnects, in accordance with various embodiments. The optical interconnects illustrated in FIGS. 11A-11H may be examples of the optical interconnects 112 of FIG. 1, and may include any embodiment or combination of embodiments of the optical interconnects described with respect to FIGS. 3-7, 8A-8B, 9A-9B, and 10A-10B.

FIG. 11A illustrates an IC structure 1100A with an optical interconnect 1112-1 between and coupled with optical interconnects 1112-2 and 1112-3. The optical interconnect 1112-1 may be an example of the optical interconnect 312 of FIG. 3, although viewed along a different cross-section. The optical interconnects 1112-2 and 1112-3 may be an example of the optical interconnect 812 of FIGS. 8A and 8B. In the example illustrated in FIG. 11A, the optical interconnect 1112-1 extends along the x-axis (e.g., parallel to conductive lines in the same layer as the optical interconnect 1112-1), and the optical interconnects 1112-2 and 1112-3 extend along the z-axis, substantially orthogonal to the optical interconnect 1112-1. The optical interconnect 1112-3 couples the optical interconnect 1112-1 with another optical interconnect or structure in a layer over the optical interconnect 1112-1, and the optical interconnect 1112-2 couples the optical interconnect 1112-1 with another optical interconnect or structure in a layer below the optical interconnect 1112-1. The optical interconnects 1112-1, 1112-2, and 1112-3 of FIG. 11A lack a shielding material around the dielectric material 332 (e.g., a shielding material that includes a metal is absent from between the dielectric material 332 and the ILD 126 around at least a portion of the optical interconnects 1112-1, 1112-2, and 1112-3).

FIG. 11B illustrates an IC structure 1100B that includes an optical interconnect 1112-4 between and coupled with optical interconnects 1112-5 and 1112-6, and further including conductive interconnects 1122-1 and 1122-2 that include a conductive material 315. In the example illustrated in FIG. 11B, the optical interconnect 1112-4 is parallel to and between the conductive interconnects 1122-1 and 1122-2. In the example illustrated in FIG. 11B, the conductive interconnects 1122-1 and 1122-2 are above and below (e.g., directly above and below) the optical interconnect 1112-4 (e.g., the conductive interconnects 1122-1 and 1122-2 and the optical interconnect 1112-4 are in a plane that is substantially orthogonal to the substrate and parallel to the conductive interconnects 1122-1 and 1122-2, such as the x-z plane shown in FIG. 11B). In one example, the conductive interconnects 1122-1 and 1122-2 are in contact with (e.g., in direct contact with, where two materials are in direct contact if there are no intervening materials between the two materials) the optical interconnect 1112-4. In one such example, a continuous portion of the dielectric material 332 is between and in contact with the conductive material 315 of the conductive interconnect 1122-1 and the conductive material 315 of the conductive interconnect 1122-2. In other examples, one or more intervening materials may be present between the conductive interconnects 1122-1, 1122-2 and the dielectric material 332 of the optical interconnect 1112-4. Thus, the IC structure 1100B includes a conductive interconnect 1122-1 (e.g., a first metal line) below, substantially parallel to, and substantially aligned with the optical interconnect 1112-4, and a conductive interconnect 1122-2 (e.g., a second metal line) above, substantially parallel to, and substantially aligned with the optical interconnect 1112-4. In some examples, the conductive interconnects 1122-1 and 1122-2 may act as a shielding material for the optical interconnect 1112-4.

FIG. 11C illustrates an IC structure 1100C with an optical interconnect 1112-5 between and coupled with optical interconnects 1112-6 and 1112-7. The IC structure 1100C of FIG. 11C is similar to the IC structure 1100A of FIG. 11A in that the optical interconnect 1112-5 is substantially parallel to conductive lines in the same layer as the optical interconnect 1112-5, and the optical interconnects 1112-6 and 1112-7 are substantially orthogonal to the optical interconnect 1112-5. The optical interconnect 1112-5 further includes a shielding material over or surrounding at least a portion of the optical interconnect 1112-5. The optical interconnect 1112-5 may be an example of the optical interconnect 412 of FIG. 4, although viewed along a different cross-section. Thus, the shielding material 314 lining the bottom of the optical interconnect 1112-5 is visible in FIG. 11C, but shielding material 314 which may be present on the sidewalls of the optical interconnect 1112-5 (such as shown in FIG. 4), is not visible in the cross-sectional view shown in FIG. 11C. As can be seen in the example illustrated in FIG. 11C, the shielding material 314 is present along the bottom of the optical interconnect 1112-5 except where the optical via (e.g., the optical interconnect 1112-6) is coupled with a bottom portion of the optical interconnect 1112-5. Therefore, the dielectric material 332 of the optical interconnect 1112-6 may be in contact with (e.g., in direct contact with) the dielectric material 332 of the optical interconnect 1112-5 to enable transmission of optical signals along an optical transmission path that includes the optical interconnects 1112-5, 1112-6, and 1112-7.

FIG. 11D illustrates an IC structure 1100D with an optical interconnect 1112-8 between and coupled with optical interconnects 1112-9 and 1112-10. The IC structure 1100D of FIG. 11D is similar to the IC structure 1100C of FIG. 11C in that the optical interconnect 1112-8 is substantially parallel to conductive lines in the same layer as the optical interconnect 1112-8, and the optical interconnect 1112-8 includes a shielding material over or around at least a portion of the optical interconnect 1112-8. The optical interconnect 1112-8 may be an example of the optical interconnect 512 of FIG. 5, although viewed along a different cross-section. Thus, the shielding material 314 lining the bottom and top of the optical interconnect 1112-8 is visible in FIG. 11D, but shielding material 314 which may be present on the sidewalls of the optical interconnect 1112-8 (such as shown in FIG. 5), is not visible in the cross-sectional view shown in FIG. 11D. As can be seen in the example illustrated in FIG. 11D, the shielding material 314 is present along the bottom of the optical interconnect 1112-8 and over the top of the optical interconnect 1112-8 except where the optical vias (e.g., the optical interconnects 1112-9 and 1112-10) are coupled with a bottom portion and a top portion of the optical interconnect 1112-8. Therefore, the dielectric material 332 of the optical interconnect 1112-9 may be in contact with (e.g., in direct contact with) the dielectric material 332 of the optical interconnect 1112-8, and the dielectric material 332 of the optical interconnect 1112-10 may be in contact with (e.g., in direct contact with) the dielectric material 332 of the optical interconnect 1112-8 to enable transmission of optical signals along an optical transmission path that includes the optical interconnects 1112-8, 1112-9, and 1112-10.

FIG. 11E illustrates an IC structure 1100E with an optical interconnect 1112-11. The cross-sectional view illustrated in FIG. 11E is along a plane that is substantially parallel to the device region (e.g., along the x-y plane as shown in FIG. 11E). The optical interconnect 1112-11 may be coupled with an optical interconnect 1112-12 (e.g., an optical via) in a layer above the optical interconnect 1112-11, as shown in FIG. 11E by the round dotted-line contour aligned with the optical interconnect 1112-11. The IC structure 1100E is similar to the IC structure 1100B in that conductive interconnects 1122-3 and 1122-4 are present on either side of the optical interconnect 1112-11. However, the location of the conductive interconnects 1122-3, 1122-4 is different in FIG. 11E than in the example illustrated in FIG. 11B. Specifically, in the example illustrated in FIG. 11E, the conductive interconnects 1122-3 and 1122-4 are in the same layer or plane as the optical interconnect 1112-11 rather than above and below the optical interconnect 1112-11. In one example, the conductive interconnects 1122-3 and 1122-4 are in contact with (e.g., in direct contact with) the optical interconnect 1112-11. In one such example, a continuous portion of the dielectric material 332 is between and in contact with the conductive material 315 of the conductive interconnect 1122-3 and the conductive material 315 of the conductive interconnect 1122-4. In other examples, one or more intervening materials may be present between the conductive interconnects 1122-3, 1122-4 and the dielectric material 332 of the optical interconnect 1112-11. Thus, the IC structure 1100E includes a conductive interconnect 1122-3 (e.g., a first metal line) and a conductive interconnect 1122-4 (e.g., a second metal line) on either side of (e.g., adjacent to) the optical interconnect 1112-11 in a plane substantially parallel to the device region, wherein the first metal line and the second metal line are substantially parallel to the optical interconnect 1112-11. the conductive interconnects 1122-3 and 1122-4 may act as a shielding material for the optical interconnect 1112-11.

FIG. 11F illustrates an IC structure 1100F with an optical interconnect 1112-13 between and coupled with optical interconnects 1112-14 and 1112-15. The IC structure 1100F of FIG. 11F is similar to the IC structure 1100D of FIG. 11D in that the optical interconnect 1112-8 is substantially parallel to conductive lines in the same layer as the optical interconnect 1112-8, and the optical interconnect 1112-8 includes a shielding material over or around at least a portion (e.g., over a top, bottom, and on sidewalls) of the optical interconnect 1112-13. The IC structure 1100F further includes a conductive interconnect 1122-5 coupled with the shielding material around the optical interconnect 1112-13. In one such example, the conductive interconnect 1122-5 may apply a voltage to the shielding material 314 to modulate the optical signal being transmitted in the optical interconnects 1112-3. In one such example, the optical interconnects 1112-3 may be formed directly over the conductive interconnect 1122-5 so that the conductive material 315 of the conductive interconnect 1122-5 is in contact with (e.g., in direct contact with) the shielding material 314 around the optical interconnect 1112-13. Although FIG. 11F illustrates a conductive via coupled with a bottom of the optical interconnect 1112-13, in other examples a conductive via may be coupled with a top of the optical interconnect 1112-13 to modulate the optical signal. Thus, the example illustrated in FIG. 11F includes a conductive interconnect 1122-5 coupled with the shielding material 314 (e.g., in direct contact with the shielding material 314 for modulation).

FIG. 11G illustrates an IC structure 1100G with an optical interconnect 1112-16 between and coupled with optical interconnects 1112-17 and 1112-18. The IC structure 1100G of FIG. 11G is similar to the IC structure 1100D of FIG. 11D in that the optical interconnect 1112-16 is substantially parallel to conductive lines in the same layer as the optical interconnect 1112-16, and the optical interconnect 1112-16 includes a shielding material over or around at least a portion (e.g., over a top, bottom, and on sidewalls) of the optical interconnect 1112-16. The IC structure 1100G differs of FIG. 11G differs from the IC structure 1100D in that the IC structure 1100G includes the shielding material 314 on sidewalls of the optical vias (e.g., of the optical interconnects 1112-17 and 1112-18 that are substantially orthogonal to the substrate) in addition to the shielding material 314 around the optical interconnect 1112-16. The optical interconnect 1112-16 may be an example of the optical interconnect 512 of FIG. 5, although viewed along a different cross-section. The optical interconnects 1112-17 and 1112-18 may be an example of the optical interconnect 912 of FIGS. 9A and 9B.

Thus, the IC structure 1100G includes a shielding material 314 lining the bottom, top, and sidewalls of the optical interconnect 1112-16, as well as on sidewalls of the optical interconnects 1112-17 and 1112-18. Similar to the example IC structure 1100D, there are discontinuities in the shielding material where the optical interconnects meet, so that there is a continuous path of the dielectric material 332 along the optical interconnects 1112-16, 1112-17, and 1112-18. In the example illustrated in FIG. 11G, the shielding material 314 along the bottom of the optical interconnect 1112-16 is in contact with (e.g., in direct contact with) the shielding material 314 on sidewalls of the optical interconnect 1112-17. Similarly, the shielding material 314 over the top of the optical interconnect 1112-16 is in contact with (e.g., in direct contact with) the shielding material 314 on sidewalls of the optical interconnect 1112-18. Thus, in some examples, the shielding material 314 encapsulates the optical path that includes both the optical interconnect 1112-16 as well as the optical interconnects 1112-17 and 1112-18.

FIG. 11H illustrates an IC structure 1100H with an optical interconnect 1112-19 between and coupled with optical interconnects 1112-20 and 1112-21. The IC structure 1100H of FIG. 11H is similar to the IC structure 1100G of FIG. 11G in that the optical interconnect 1112-19 is substantially parallel to conductive lines in the same layer as the optical interconnect 1112-19, and the IC structure 1100H includes a shielding material 314 around the optical interconnects 1112-19, 1112-20, and 1112-21. The IC structure 1100H differs of FIG. 11H differs from the IC structure 1100G in that the IC structure 1100H includes conductive interconnects within the optical interconnects. For example, the optical interconnect 1112-19 includes a layer of the dielectric material 332 surrounding a conductive interconnect 1122-7. The optical interconnect 1112-20 includes a layer of the dielectric material 332 surrounding a conductive interconnect 1122-6. Similarly, the optical interconnect 1112-21 includes a layer of the dielectric material 332 surrounding a conductive interconnect 1122-8. The optical interconnect 1112-19 may be an example of the optical interconnect 712 of FIG. 7 (with further shielding material 314 over the top of the optical interconnect 1112-19), although viewed along a different cross-section. The optical interconnects 1112-20 and 1112-21 may be an example of the optical interconnect 1012 of FIGS. 10A and 10B. In the example illustrated in FIG. 11H, the dielectric material 332 of the optical interconnects 1112-19, 1112-20, and 1112-21 surrounds the respective conductive interconnects 1122-7, 1122-6, and 1122-8 (e.g., there is a conductive core in the dielectric material 332 of the optical interconnects 1112-19, 1112-20 and 1112-21 that forms the conductive interconnects 1122-7, 1122-6, and 1122-8). As can be seen in FIG. 11H, the IC structure includes a continuous portion of the conductive material 315 in the optical interconnects 1112-19, 1112-20 and 1112-21 to form an electrically conductive pathway in the optical interconnects 1112-19, 1112-20 and 1112-21. Similarly, there is a continuous portion of the dielectric material 332 around the conductive interconnects 1122-6, 1122-7, and 1122-8 to form an optical pathway around the conductive interconnects 1122-6, 1122-7, and 1122-8.

Thus, FIGS. 11A-11H illustrate cross-sectional views of IC structures including optical interconnects, in accordance with various embodiments. The different embodiments discussed above may be combined (e.g., the IC structure 1100A may include a conductive core that forms a conductive interconnect, the IC structure 1100C may include a shielding material around the optical interconnects 1112-6 and 1112-7, etc.).

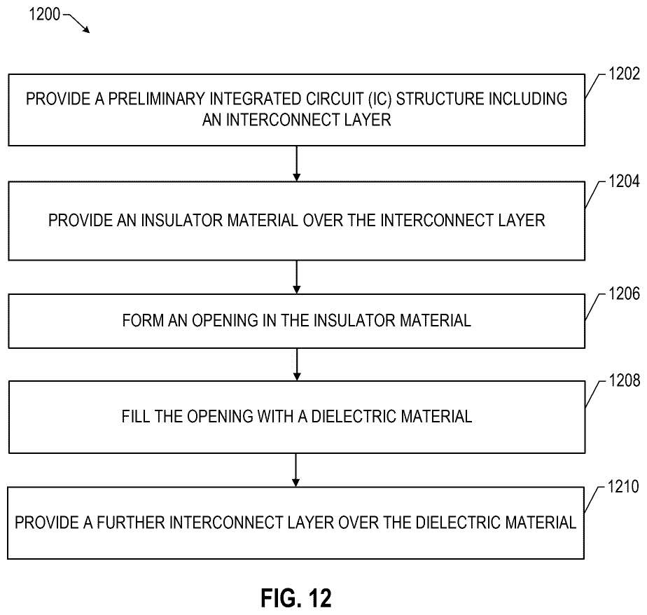

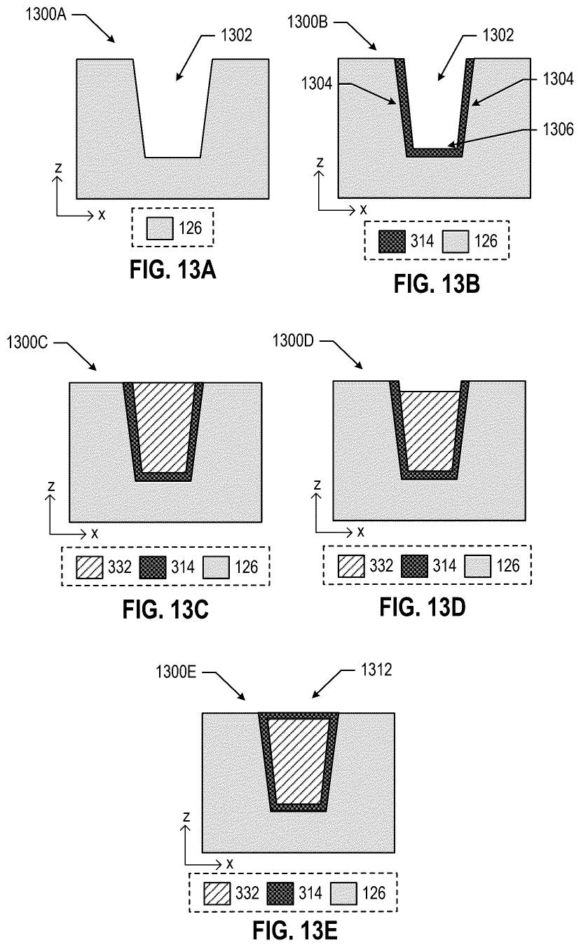

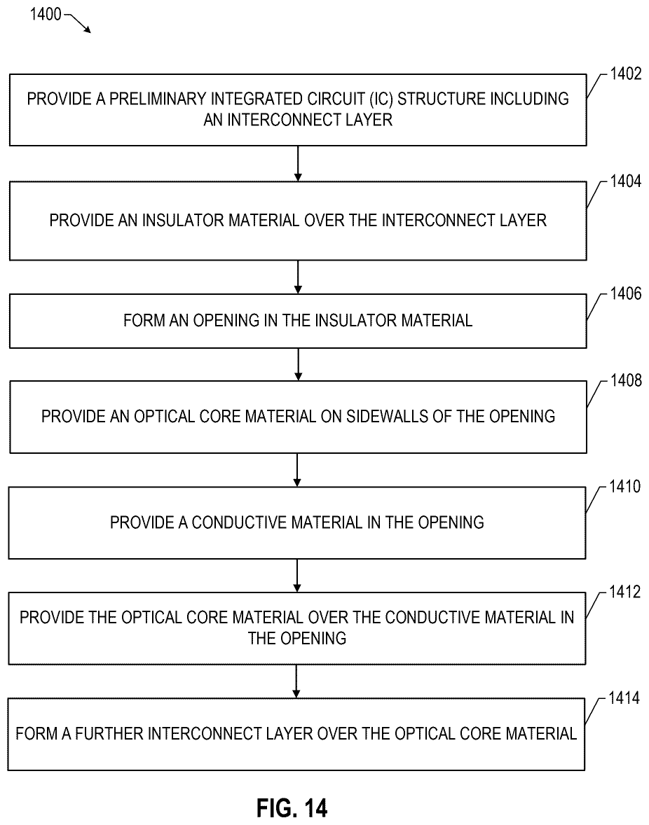

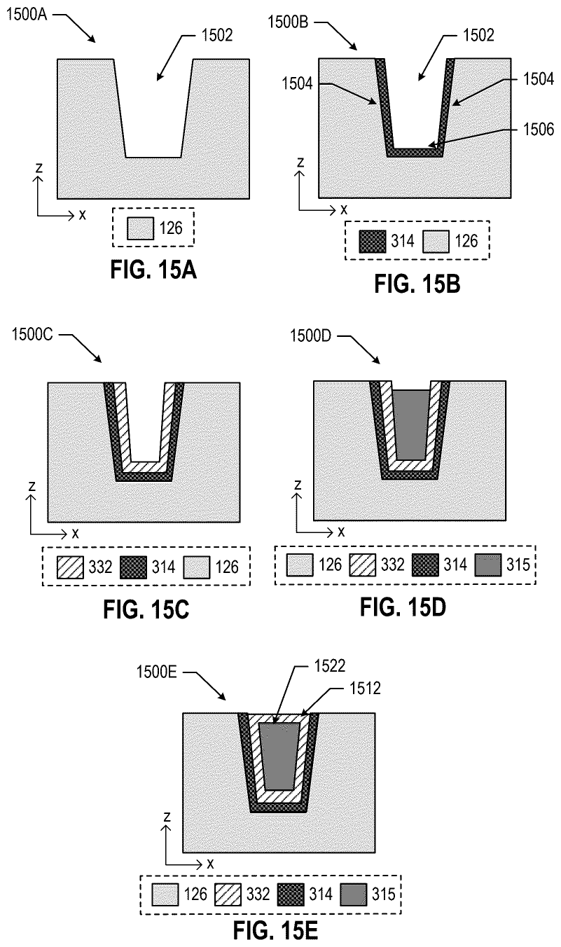

FIGS. 12 and 14 are flow diagrams of example methods 1200 and 1400 for fabricating an IC structure including backend optical interconnects. FIGS. 13A-13E provide different views at various stages in the fabrication of an example IC structure according to the method of FIG. 12, in accordance with some embodiments. FIGS. 15A-15E provide different views at various stages in the fabrication of an example IC structure according to the method of FIG. 14, in accordance with some embodiments. Although the operations of the methods of FIGS. 12 and 14 are illustrated once each and in a particular order, the operations may be performed in any suitable order and repeated as desired. For example, one or more operations may be performed in parallel to fabricate multiple IC structures including backend optical interconnects substantially simultaneously. In another example, the operations may be performed in a different order to reflect the structure in which backend optical interconnects will be implemented.

In addition, the example fabricating methods of FIGS. 12 and 14 may include other operations not specifically shown in FIGS. 12 and 14, such as various cleaning or planarization operations as known in the art. For example, in some embodiments, a support, as well as layers of various other materials subsequently deposited thereon, may be cleaned prior to, after, or during any of the processes of the methods described herein, e.g., to remove oxides, surface-bound organic and metallic contaminants, as well as subsurface contamination. In some embodiments, cleaning may be carried out using e.g., a chemical solutions (such as peroxide), and/or with ultraviolet (UV) radiation combined with ozone, and/or oxidizing the surface (e.g., using thermal oxidation) then removing the oxide (e.g., using hydrofluoric acid (HF)). In another example, the intermediate IC structures described herein may be planarized prior to, after, or during any of the processes of the method of FIGS. 12 and 14 described herein, e.g., to remove overburden or excess materials. In some embodiments, planarization may be carried out using either wet or dry planarization processes, e.g., planarization be a chemical mechanical planarization (CMP), which may be understood as a process that utilizes a polishing surface, an abrasive and a slurry to remove the overburden and planarize the surface.

Turning to FIG. 12, the method 1200 begins with a process 1202 of providing a preliminary IC structure including an interconnect layer, a process 1204 of providing an insulator material over the interconnect layer, and a process 1206 of forming an opening in the insulator material. The IC structure 1300A of FIG. 13A is an example resulting IC structure of the processes 1202, 1204, and 1206. The IC structure 1300A depicts a layer of an insulator material, such as an ILD 126. The ILD 126 may be any suitable ILD, such as those discussed above. The ILD 126 may be deposited using any suitable deposition technique, such as atomic layer deposition (ALD), chemical vapor deposition (CVD), plasma enhanced CVD (PECVD), or/and physical vapor deposition (PVD) processes such as sputter. The IC structure 1300A further includes an opening 1302 in the ILD 126. Any suitable etching technique, e.g., a dry etch, such as e.g., radio frequency (RF) reactive ion etch (RIE) or inductively coupled plasma (ICP) RIE may be used to form the opening 1302. The opening 1302 may be, for example, a trench or a via opening. In one example, forming the opening 1302 involves forming the forming a trench parallel with the interconnect layer. The example illustrated in FIG. 13A may be a trench that extends along the y-axis as shown in FIG. 13A, where the y-axis is going into and coming out of the page. Although the details of the interconnect layer below the opening 1302 are not shown in FIG. 13A, the IC structure 1300A may include an optical interconnect and/or a conductive interconnect exposed at the bottom of the opening 1302, to enable coupling the optical interconnect to be formed in the opening 1302 with interconnects in the underlying layer.

After forming the opening 1302, the method may involve providing a material that includes a metal on sidewalls and over a bottom of the opening 1302. The IC structure 1300B of FIG. 13B is an example resulting IC structure of the process of providing a material 314 that includes a metal (e.g., a shielding material). The material 314 may be any suitable optical shielding material, such as the examples discussed above, and may be provided with any suitable technique, such as ALD, CVD, PECVD, or/and PVD processes such as sputter. In one example, the material 314 may form a conformal layer or liner on the sidewalls and bottom of the opening 1302. In some examples, the material 314 may be provided only on the sidewalls (e.g., either with selective deposition, or by removing the material 314 from the bottom of the opening 1302). In other examples, the material 314 may not be provided over the bottom 1306 and sidewalls 1304 of the opening 1302.

Referring again to FIG. 12, the method 1200 continues with a process 1208 of filling the opening with a dielectric material. The IC structure 1300C of FIG. 13C is an example resulting IC structure of the process 1208. As can be seen in FIG. 13C, the opening has been filled with the dielectric material 332. The dielectric material 332 may be any suitable optical medium, and may be provided using any suitable technique, such as those discussed above with respect to the process 1204. In one example, the dielectric material 332 may be recessed to enable providing a shielding material over the dielectric material 332. The IC structure 1300D of FIG. 13D is an example resulting IC structure of the process of recessing the dielectric material 332. Recessing the dielectric material 332 may be performed with any suitable technique, such as the etch techniques discussed above. The method may then involve providing the material 314 over the dielectric material 332. The IC structure 1300E of FIG. 13E is an example resulting IC structure of the process of providing the material 314 over the dielectric material 332. Providing the material 314 over the dielectric material 332 may involve any suitable deposition technique, such as those discussed above. The resulting IC structure 1300E may include a portion of the dielectric material 332 that is encapsulated on four sides by the material 314. The method 1200 may continue with a process 1210 of providing one or more further interconnect layers over the dielectric material 332 (e.g., over the IC structure 1300E), where the one or more further interconnect layers may include further optical interconnects and further conductive interconnects.

FIG. 14 is a flow diagram of another example method 1400 for fabricating an IC structure including backend optical interconnects, in which the optical medium is surrounding a conductive interconnect. Turning to FIG. 14, the method 1400 begins with a process 1402 of providing a preliminary IC structure including an interconnect layer, a process 1404 of providing an insulator material over the interconnect layer, and a process 1406 of forming an opening in the insulator material. The IC structure 1500A of FIG. 15A is an example resulting IC structure of the processes 1402, 1404, and 1406. The processes 1402, 1404, and 1406 may be substantially the same as the processes 1202, 1204, and 1206, respectively.

After forming the opening 1502, the method may involve providing a material that includes a metal on sidewalls and over a bottom of the opening 1502. The IC structure 1500B of FIG. 15B is an example resulting IC structure of the process of providing a material 314 that includes a metal (e.g., a shielding material). Other examples may omit the material 314 from the sidewalls 1504 and/or from the bottom 1506 of the opening 1502.

Referring again to FIG. 14, the method 1400 continues with a process 1408 of providing an optical core material on sidewalls of the opening. The IC structure 1500C of FIG. 15C is an example resulting IC structure of the process 1408. As can be seen in FIG. 15C, a layer of the dielectric material 332 is present on the sidewalls 1504 and over the bottom 1506 of the opening 1502. In one such example, the dielectric material 332 is a substantially conformal layer of the dielectric material 332. The dielectric material 332 may be provided in accordance with any suitable deposition technique, such as those discussed above.

The method 1400 continues with a process 1410 of providing a conductive material in the opening (e.g., substantially filling the opening). The IC structure 1500D of FIG. 15D is an example resulting IC structure of the process 1410. As can be seen in FIG. 15D, a conductive material 315 is substantially filling the opening 1502 over the dielectric material 332. The region of the conductive material 315 may be formed according to any suitable deposition technique. In the example illustrated in FIG. 15D, the conductive material 315 does not completely fill the opening 1502, which may be achieved by, e.g., filling the opening 1502, and then recessing the conductive material 315.

The method 1400 continues with a process 1412 of providing the optical core material over the conductive material in the opening. The IC structure 1500E of FIG. 15E is an example resulting IC structure of the process 1412 of providing the dielectric material 332 over the conductive material 315. The method may further involve providing the material shielding material 314 over the dielectric material 332. In other examples, the shielding material may not be provided over the dielectric material 332.

Referring again to FIG. 14, the method 1400 may continue with a process 1414 of providing one or more further interconnect layers over the optical core material (e.g., over the IC structure 1300E), where the one or more further interconnect layers may include further optical interconnects and further conductive interconnects.

Thus, FIGS. 12 and 14 illustrate methods 1200 and 1400 for fabricating an IC structure including backend optical interconnects. Performing the methods 1200 or 1400 may result in several features in the final IC structure that are characteristic of the use of the methods 1200 or 1400. For example, one such feature is illustrated in the IC structure shown in FIG. 13E, in which an IC structure 1300E includes an optical interconnect 1312 including a dielectric material 332 in a BEOL layer, and which may include a shielding material 314 around one or more portions of the optical interconnect 1312. Another such feature is illustrated in the IC structure shown in FIG. 15E, in which an IC structure 1500E includes an optical interconnect 1512 including a dielectric material 332 in a BEOL layer, where the optical interconnect 1512 is surrounding a conductive interconnect 1522 (e.g., an electrically conductive core in the dielectric material 332 forms the conductive interconnect 1522).

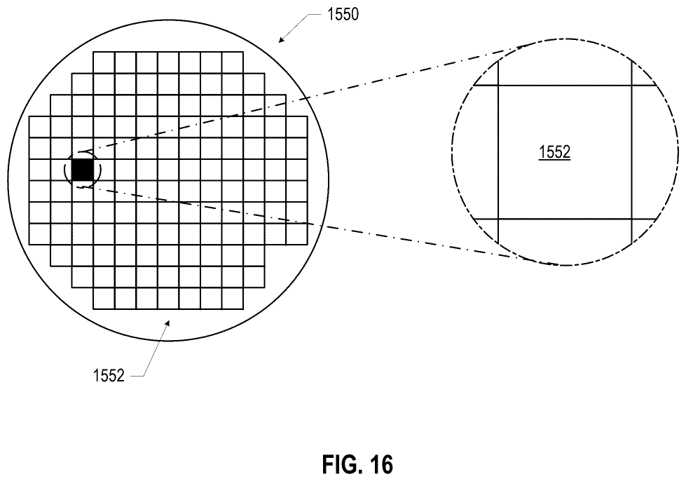

IC structures including backend optical interconnects in accordance with techniques described herein may be included in any suitable electronic component or electronic device. FIGS. 16-19 illustrate various examples of apparatuses that may include one or more of the IC structures with backend optical interconnects disclosed herein.

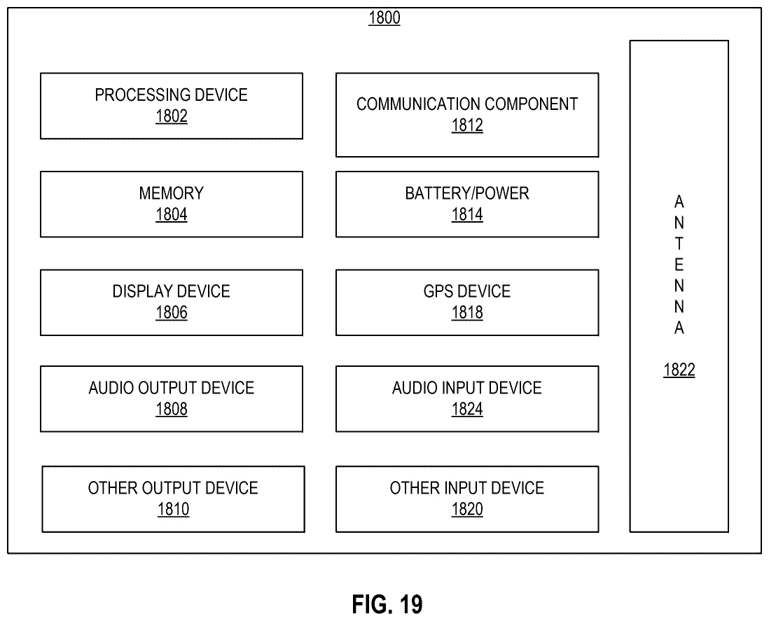

FIG. 16 is a top view of a wafer 1550 and dies 1552 that may include one or more IC structures in accordance with any of the embodiments disclosed herein. The wafer 1550 may be composed of semiconductor material and may include one or more dies 1552 having IC structures formed on a surface of the wafer 1550. Each of the dies 1552 may be a repeating unit of a semiconductor product that includes any suitable IC. After the fabrication of the semiconductor product is complete, the wafer 1550 may undergo a singulation process in which the dies 1552 are separated from one another to provide discrete “chips” of the semiconductor product. In some embodiments, the wafer 1550 or the die 1552 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 1552. For example, a memory array formed by multiple memory devices may be formed on a same die 1552 as a processing device (e.g., the processing device 1802 of FIG. 19) or other logic that is configured to store information in the memory devices or execute instructions stored in the memory array.

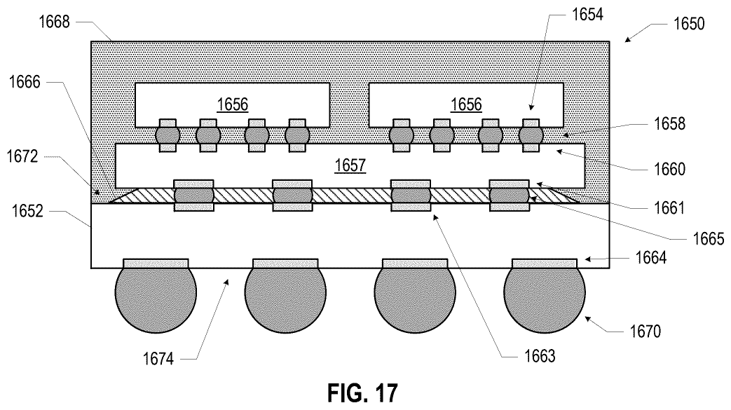

FIG. 17 is a side, cross-sectional view of an example IC package 1650 that may include one or more IC structures with backend optical interconnects in accordance with any of the embodiments disclosed herein. In some embodiments, the IC package 1650 may be a system-in-package (SiP).

The package substrate 1652 may be formed of a dielectric material (e.g., a ceramic, a buildup film, an epoxy film having filler particles therein, glass, an organic material, an inorganic material, combinations of organic and inorganic materials, embedded portions formed of different materials, etc.), and may have conductive pathways extending through the dielectric material between the face 1672 and the face 1674, or between different locations on the face 1672, and/or between different locations on the face 1674.

The package substrate 1652 may include conductive contacts 1663 that are coupled to conductive pathways (not shown) through the package substrate 1652, allowing circuitry within the dies 1656 and/or the interposer 1657 to electrically couple to various ones of the conductive contacts 1664 (or to devices included in the package substrate 1652, not shown).

The IC package 1650 may include an interposer 1657 coupled to the package substrate 1652 via conductive contacts 1661 of the interposer 1657, first-level interconnects 1665, and the conductive contacts 1663 of the package substrate 1652. The first-level interconnects 1665 illustrated in FIG. 17 are solder bumps, but any suitable first-level interconnects 1665 may be used. In some embodiments, no interposer 1657 may be included in the IC package 1650; instead, the dies 1656 may be coupled directly to the conductive contacts 1663 at the face 1672 by first-level interconnects 1665. More generally, one or more dies 1656 may be coupled to the package substrate 1652 via any suitable structure (e.g., a silicon bridge, an organic bridge, one or more waveguides, one or more interposers, wirebonds, etc.).

The IC package 1650 may include one or more dies 1656 coupled to the interposer 1657 via conductive contacts 1654 of the dies 1656, first-level interconnects 1658, and conductive contacts 1660 of the interposer 1657. The conductive contacts 1660 may be coupled to conductive pathways (not shown) through the interposer 1657, allowing circuitry within the dies 1656 to electrically couple to various ones of the conductive contacts 1661 (or to other devices included in the interposer 1657, not shown). The first-level interconnects 1658 illustrated in FIG. 17 are solder bumps, but any suitable first-level interconnects 1658 may be used. As used herein, a “conductive contact” may refer to a portion of conductive material (e.g., metal) serving as an interface between different components; conductive contacts may be recessed in, flush with, or extending away from a surface of a component, and may take any suitable form (e.g., a conductive pad or socket).

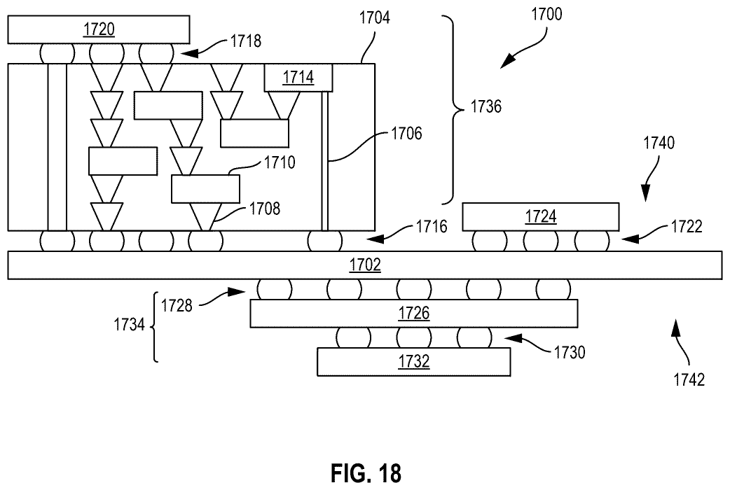

In some embodiments, an underfill material 1666 may be disposed between the package substrate 1652 and the interposer 1657 around the first-level interconnects 1665, and a mold compound 1668 may be disposed around the dies 1656 and the interposer 1657 and in contact with the package substrate 1652. In some embodiments, the underfill material 1666 may be the same as the mold compound 1668. Example materials that may be used for the underfill material 1666 and the mold compound 1668 are epoxy mold materials, as suitable. Second-level interconnects 1670 may be coupled to the conductive contacts 1664. The second-level interconnects 1670 illustrated in FIG. 17 are solder balls (e.g., for a ball grid array arrangement), but any suitable second-level interconnects 1670 may be used (e.g., pins in a pin grid array arrangement or lands in a land grid array arrangement). The second-level interconnects 1670 may be used to couple the IC package 1650 to another component, such as a circuit board (e.g., a motherboard), an interposer, or another IC package, as known in the art and as discussed below with reference to FIG. 18.

The dies 1656 may take the form of any of the embodiments of the die 1552 discussed herein. In embodiments in which the IC package 1650 includes multiple dies 1656, the IC package 1650 may be referred to as a multi-chip package (MCP). The dies 1656 may include circuitry to perform any desired functionality. For example, or more of the dies 1656 may be logic dies (e.g., silicon-based dies), and one or more of the dies 1656 may be memory dies (e.g., high bandwidth memory).

Although the IC package 1650 illustrated in FIG. 17 is a flip chip package, other package architectures may be used. For example, the IC package 1650 may be a ball grid array (BGA) package, such as an embedded wafer-level ball grid array (eWLB) package. In another example, the IC package 1650 may be a wafer-level chip scale package (WLCSP) or a panel fanout (FO) package.

Although two dies 1656 are illustrated in the IC package 1650 of FIG. 17, an IC package 1650 may include any desired number of dies 1656. An IC package 1650 may include additional passive components, such as surface-mount resistors, capacitors, and inductors disposed on the first face 1672 or the second face 1674 of the package substrate 1652, or on either face of the interposer 1657. More generally, an IC package 1650 may include any other active or passive components known in the art.

FIG. 18 is a side, cross-sectional view of an IC device assembly 1700 that may include one or more IC packages or other electronic components (e.g., a die) including one or more IC structures with backend optical interconnects in accordance with any of the embodiments disclosed herein. The IC device assembly 1700 includes a number of components disposed on a circuit board 1702 (which may be, e.g., a motherboard). The IC device assembly 1700 includes components disposed on a first face 1740 of the circuit board 1702 and an opposing second face 1742 of the circuit board 1702; generally, components may be disposed on one or both faces 1740 and 1742. Any of the IC packages discussed below with reference to the IC device assembly 1700 may take the form of any of the embodiments of the IC package 1650 discussed above with reference to FIG. 17 (e.g., may include one or more IC structures in accordance with embodiments described herein).

In some embodiments, the circuit board 1702 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate.

The IC device assembly 1700 illustrated in FIG. 18 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702, and may include solder balls (as shown in FIG. 18), male and female portions of a socket, an adhesive, an underfill material, and/or any other suitable electrical and/or mechanical coupling structure.

The package-on-interposer structure 1736 may include an IC package 1720 coupled to a package interposer 1704 by coupling components 1718. The coupling components 1718 may take any suitable form for the application, such as the forms discussed above with reference to the coupling components 1716. Although a single IC package 1720 is shown in FIG. 18, multiple IC packages may be coupled to the package interposer 1704; indeed, additional interposers may be coupled to the package interposer 1704. The package interposer 1704 may provide an intervening substrate used to bridge the circuit board 1702 and the IC package 1720. The IC package 1720 may be or include, for example, a die (the die 1552 of FIG. 16), an IC device, or any other suitable component. Generally, the package interposer 1704 may spread a connection to a wider pitch or reroute a connection to a different connection. For example, the package interposer 1704 may couple the IC package 1720 (e.g., a die) to a set of BGA conductive contacts of the coupling components 1716 for coupling to the circuit board 1702. In the embodiment illustrated in FIG. 18, the IC package 1720 and the circuit board 1702 are attached to opposing sides of the package interposer 1704; in other embodiments, the IC package 1720 and the circuit board 1702 may be attached to a same side of the package interposer 1704. In some embodiments, three or more components may be interconnected by way of the package interposer 1704.

In some embodiments, the package interposer 1704 may be formed as a PCB, including multiple metal layers separated from one another by layers of dielectric material and interconnected by electrically conductive vias. In some embodiments, the package interposer 1704 may be formed of an epoxy resin, a fiberglass-reinforced epoxy resin, an epoxy resin with inorganic fillers, a ceramic material, or a polymer material such as polyimide. In some embodiments, the package interposer 1704 may be formed of alternate rigid or flexible materials that may include the same materials described above for use in a semiconductor substrate, such as silicon, germanium, and other group III-V and group IV materials. The package interposer 1704 may include metal lines 1710 and vias 1708, including but not limited to through-silicon vias (TSVs) 1706. The package interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the package interposer 1704. The package-on-interposer structure 1736 may take the form of any of the package-on-interposer structures known in the art.

The IC device assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC device assembly 1700 illustrated in FIG. 18 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

FIG. 19 is a block diagram of an example electrical device 1800 that may include one or more IC structures with backend optical interconnects in accordance with any of the embodiments disclosed herein. For example, any suitable ones of the components of the electrical device 1800 may include one or more of the IC device assemblies 1700, IC packages 1650, or dies 1552 disclosed herein. A number of components are illustrated in FIG. 19 as included in the electrical device 1800, but any one or more of these components may be omitted or duplicated, as suitable for the application. In some embodiments, some or all of the components included in the electrical device 1800 may be attached to one or more motherboards. In some embodiments, some or all of these components are fabricated onto a single system-on-a-chip (SoC) die.

Additionally, in various embodiments, the electrical device 1800 may not include one or more of the components illustrated in FIG. 19, but the electrical device 1800 may include interface circuitry for coupling to the one or more components. For example, the electrical device 1800 may not include a display device 1806, but may include display device interface circuitry (e.g., a connector and driver circuitry) to which a display device 1806 may be coupled. In another set of examples, the electrical device 1800 may not include an audio input device 1824 or an audio output device 1808, but may include audio input or output device interface circuitry (e.g., connectors and supporting circuitry) to which an audio input device 1824 or audio output device 1808 may be coupled.

The electrical device 1800 may include a processing device 1802 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1802 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The electrical device 1800 may include a memory 1804, which may itself include one or more memory devices such as volatile memory (e.g., dynamic random access memory (DRAM)), nonvolatile memory (e.g., read-only memory (ROM)), flash memory, solid state memory, and/or a hard drive. In some embodiments, the memory 1804 may include memory that shares a die with the processing device 1802. This memory may be used as cache memory and may include embedded dynamic random access memory (eDRAM) or spin transfer torque magnetic random access memory (STT-MRAM).

In some embodiments, the electrical device 1800 may include a communication chip 1812 (e.g., one or more communication chips). For example, the communication chip 1812 may be configured for managing wireless communications for the transfer of data to and from the electrical device 1800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 1812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1812 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1812 may operate in accordance with other wireless protocols in other embodiments. The electrical device 1800 may include an antenna 1822 to facilitate wireless communications and/or to receive other wireless communications (such as AM or FM radio transmissions).

In some embodiments, the communication chip 1812 may manage wired communications, such as electrical, optical, or any other suitable communication protocols (e.g., the Ethernet). As noted above, the communication chip 1812 may include multiple communication chips. For instance, a first communication chip 1812 may be dedicated to shorter-range wireless communications such as Wi-Fi or Bluetooth, and a second communication chip 1812 may be dedicated to longer-range wireless communications such as global positioning system (GPS), EDGE, GPRS, CDMA, WiMAX, LTE, EV-DO, or others. In some embodiments, a first communication chip 1812 may be dedicated to wireless communications, and a second communication chip 1812 may be dedicated to wired communications.

The electrical device 1800 may include battery/power circuitry 1814. The battery/power circuitry 1814 may include one or more energy storage devices (e.g., batteries or capacitors) and/or circuitry for coupling components of the electrical device 1800 to an energy source separate from the electrical device 1800 (e.g., AC line power).

The electrical device 1800 may include a display device 1806 (or corresponding interface circuitry, as discussed above). The display device 1806 may include any visual indicators, such as a heads-up display, a computer monitor, a projector, a touchscreen display, a liquid crystal display (LCD), a light-emitting diode display, or a flat panel display.

The electrical device 1800 may include an audio output device 1808 (or corresponding interface circuitry, as discussed above). The audio output device 1808 may include any device that generates an audible indicator, such as speakers, headsets, or earbuds.

The electrical device 1800 may include an audio input device 1824 (or corresponding interface circuitry, as discussed above). The audio input device 1824 may include any device that generates a signal representative of a sound, such as microphones, microphone arrays, or digital instruments (e.g., instruments having a musical instrument digital interface (MIDI) output).

The electrical device 1800 may include a GPS device 1818 (or corresponding interface circuitry, as discussed above). The GPS device 1818 may be in communication with a satellite-based system and may receive a location of the electrical device 1800, as known in the art.

The electrical device 1800 may include an other output device 1810 (or corresponding interface circuitry, as discussed above). Examples of the other output device 1810 may include an audio codec, a video codec, a printer, a wired or wireless transmitter for providing information to other devices, or an additional storage device.

The electrical device 1800 may include an other input device 1820 (or corresponding interface circuitry, as discussed above). Examples of the other input device 1820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 1800 may have any desired form factor, such as a handheld or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server device or other networked computing component, a printer, a scanner, a monitor, a set-top box, an entertainment control unit, a vehicle control unit, a digital camera, a digital video recorder, or a wearable electrical device. In some embodiments, the electrical device 1800 may be any other electronic device that processes data.

The following paragraphs provide various examples of the embodiments disclosed herein.

Example 1 provides an IC structure, including a device region; a first interconnect layer over the device region; a second interconnect layer over the first interconnect layer; and a third interconnect layer between the first interconnect layer and the second interconnect layer, where the third interconnect layer includes a first dielectric material, a conductive interconnect in the first dielectric material, and an optical interconnect in the first dielectric material and coplanar with the conductive interconnect, where the optical interconnect includes a second dielectric material.

Example 2 provides the IC structure of example 1, where: the conductive interconnect is a metal line in a plane substantially parallel to the device region, and the optical interconnect is substantially parallel to the metal line (e.g., and in the plane).

Example 3 provides the IC structure of example 2, where: the conductive interconnect has a first thickness, and the optical interconnect has a second thickness that is substantially the same as the first thickness.

Example 4 provides the IC structure of any one of examples 2-3, where: the metal line is one of a plurality of metal lines with a pitch that is greater than about 250 nanometers (e.g., in an upper metal layer).

Example 5 provides the IC structure of any one of examples 2-4, further including a material including a metal on sidewalls and over a bottom of the optical interconnect (e.g., shielding material around three sides of the optical line).

Example 6 provides the IC structure of example 5, where: the material including the metal is further over a top of the optical interconnect.

Example 7 provides the IC structure of any one of examples 5-6, where: the material on the sidewalls has a thickness in a range of about 1-30% of a width of the optical interconnect.

Example 8 provides the IC structure of any one of examples 5-7, where: the material includes one or more of: tantalum nitride, titanium nitride, tungsten, ruthenium, molybdenum, copper, titanium tantalum.

Example 9 provides the IC structure of any one of examples 5-8, where the conductive interconnect includes a first conductive interconnect, and where the IC structure further includes a second conductive interconnect coupled with the material (e.g., in direct contact with the material for modulation).

Example 10 provides the IC structure of any one of examples 1-9, further including a first metal line above, substantially parallel to, and substantially aligned with the optical interconnect; and a second metal line below, substantially parallel to, and substantially aligned with the optical interconnect.

Example 11 provides the IC structure of any one of examples 1-9, further including a first metal line and a second metal line on either side of the optical interconnect (e.g., adjacent to) in a plane substantially parallel to the device region, where the first metal line and the second metal line are substantially parallel to the optical interconnect.

Example 12 provides the IC structure of example 1, where: the optical interconnect is a via through at least the third interconnect layer.

Example 13 provides the IC structure of example 12, further including a material including a metal on sidewalls of the via.

Example 14 provides the IC structure of any one of examples 1-13, where: the optical interconnect is a first optical interconnect, and the first optical interconnect is between and coupled with a second optical interconnect in the first interconnect layer and a third optical interconnect in the second interconnect layer.

Example 15 provides the IC structure of any one of examples 1-14, where: the second dielectric material includes one or more of: aluminum nitride, silicon carbide, aluminum scandium nitride, aluminum silicon nitride, and lithium niobate.

Example 16 provides the IC structure of any one of examples 1-15, where: the second dielectric material of the optical interconnect surrounds the conductive interconnect (e.g., there is a metal core in the second dielectric material that forms the conductive interconnect).

Example 17 provides an IC structure, including a device region; an interconnect layer over the device region; a first conductive interconnect and a second conductive interconnect in the interconnect layer; and a waveguide between the first conductive interconnect and the second conductive interconnect, where at least a portion of the waveguide is coplanar with the first conductive interconnect and the second conductive interconnect.

Example 18 provides the IC structure of example 17, where: the waveguide is substantially orthogonal to the first conductive interconnect (e.g., the waveguide is an optical via), and the waveguide includes a core material including a dielectric material and a shielding material surrounding the dielectric material, where the shielding material includes a metal.

Example 18 provides an IC structure according to any one of examples 1-17, where the IC structure includes or is a part of a central processing unit.

Example 19 provides an IC structure according to any one of examples 1-18, where the IC structure includes or is a part of a memory device.

Example 20 provides an IC structure according to any one of examples 1-19, where the IC structure includes or is a part of a logic circuit.

Example 21 provides an IC structure according to any one of examples 1-20, where the IC structure includes or is a part of input/output circuitry.

Example 22 provides an IC structure according to any one of examples 1-21, where the IC structure includes or is a part of a field programmable gate array transceiver.

Example 23 provides an IC structure according to any one of examples 1-22, where the IC structure includes or is a part of a field programmable gate array logic.

Example 24 provides an IC structure according to any one of examples 1-23, where the IC structure includes or is a part of a power delivery circuitry.

Example 25 provides an IC package that includes an IC die including an IC structure according to any one of examples 1-24; and a further IC component, coupled to the IC die.

Example 26 provides an IC package according to example 25 where the further IC component includes a package substrate.

Example 27 provides an IC package according to example 25, where the further IC component includes an interposer.

Example 28 provides an IC package according to example 25, where the further IC component includes a further IC die.

Example 29 provides a computing device that includes a carrier substrate and an IC structure coupled to the carrier substrate, where the IC structure is an IC structure according to any one of examples 1-24, or the IC structure is included in the IC package according to any one of examples 25-28.

Example 30 provides a computing device according to example 29, where the computing device is a wearable or handheld computing device.

Example 31 provides a computing device according to examples 29 or 30, where the computing device further includes one or more communication chips.

Example 32 provides a computing device according to any one of examples 29-31, where the computing device further includes an antenna.

Example 33 provides a computing device according to any one of examples 29-32, where the carrier substrate is a motherboard.

Example 34 provides a method of fabricating an IC structure, the method including providing a preliminary IC structure including an interconnect layer; providing an insulator material over the interconnect layer; forming an opening in the insulator material; filling the opening with a dielectric material; and forming a further interconnect layer over the dielectric material.

Example 35 provides the method of example 34, where: forming the opening includes forming a trench parallel with the interconnect layer.

Example 36 provides the method of example 34, where: forming the opening includes forming a via opening.

Example 37 provides the method of any one of examples 34-36, further including prior to filling the opening with the dielectric material, providing a material including a metal on sidewalls of the opening.

Example 38 provides the method of example 37, where: providing the material further includes providing the material over a bottom of the opening.

Example 39 provides the method of any one of examples 37-38, further including providing the material over the dielectric material.

Example 40 provides a method of fabricating an IC structure, the method including providing a preliminary IC structure including an interconnect layer; providing an insulator material over the interconnect layer; forming an opening in the insulator material; providing an optical core material on sidewalls of the opening; providing a conductive material in the opening (e.g., substantially filling the opening); providing the optical core material over the conductive material in the opening (e.g., to surround the conductive material); and forming a further interconnect layer over the optical core material.

Example 41 provides the method of example 40, further including prior to providing the optical core material, providing a material including a metal on the sidewalls of the opening.

Example 42 provides the method of example 41, further including providing the material over a portion of the optical core material that is over the conductive material (e.g., to surround the optical core material with the shielding material).

Example 43 provides a method according to any one of examples 34-42, where the IC structure is an IC structure according to any one of the preceding examples.

Example 44 provides a process of making an IC structure, the process including providing a preliminary IC structure including an interconnect layer; providing an insulator material over the interconnect layer; forming an opening in the insulator material; filling the opening with a dielectric material; and forming a further interconnect layer over the dielectric material.

Example 45 provides the process of example 44, where: forming the opening includes forming a trench parallel with the interconnect layer.

Example 46 provides the process of example 44, where: forming the opening includes forming a via opening.

Example 47 provides the process of any one of examples 44-46, further including prior to filling the opening with the dielectric material, providing a material including a metal on sidewalls of the opening.

Example 48 provides the process of example 47, where: providing the material further includes providing the material over a bottom of the opening.

Example 49 provides the process of any one of examples 47-48, further including providing the material over the dielectric material.

Example 50 provides a process of making an IC structure, the process including providing a preliminary IC structure including an interconnect layer; providing an insulator material over the interconnect layer; forming an opening in the insulator material; providing an optical core material on sidewalls of the opening; providing a conductive material in the opening (e.g., substantially filling the opening); providing the optical core material over the conductive material in the opening (e.g., to surround the conductive material); and forming a further interconnect layer over the optical core material.

Example 51 provides the process of example 50, further including prior to providing the optical core material, providing a material including a metal on the sidewalls of the opening.

Example 52 provides the process of example 51, further including providing the material over a portion of the optical core material that is over the conductive material (e.g., to surround the optical core material with the shielding material).

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. An integrated circuit (IC) structure, comprising:
a device region;
a first interconnect layer over the device region;
a second interconnect layer over the first interconnect layer; and
a third interconnect layer between the first interconnect layer and the second interconnect layer, wherein the third interconnect layer comprises:
a first dielectric material,
a conductive interconnect in the first dielectric material, and
an optical interconnect in the first dielectric material and coplanar with the conductive interconnect, wherein the optical interconnect comprises a second dielectric material.

2. The IC structure of claim 1, wherein:
the conductive interconnect is a metal line in a plane substantially parallel to the device region, and the optical interconnect is substantially parallel to the metal line.

3. The IC structure of claim 2, wherein:
the conductive interconnect has a first thickness, and the optical interconnect has a second thickness that is substantially the same as the first thickness.

4. The IC structure of claim 2, wherein:
the metal line is one of a plurality of metal lines with a pitch that is greater than about 250 nanometers.

5. The IC structure of claim 2, further comprising:
a material comprising a metal on sidewalls and over a bottom of the optical interconnect.

6. The IC structure of claim 5, wherein:
the material comprising the metal is further over a top of the optical interconnect.

7. The IC structure of claim 5, wherein:
the material on the sidewalls has a thickness in a range of about 1-30% of a width of the optical interconnect.

8. The IC structure of claim 5, wherein:
the material comprises one or more of:
tantalum nitride, titanium nitride, tungsten, ruthenium, molybdenum, copper, and titanium tantalum.

9. The IC structure of claim 5, wherein the conductive interconnect comprises a first conductive interconnect, and wherein the IC structure further comprises:
a second conductive interconnect coupled with the material.

10. The IC structure of claim 1, further comprising:
a first metal line above, substantially parallel to, and substantially aligned with the optical interconnect; and
a second metal line below, substantially parallel to, and substantially aligned with the optical interconnect.

11. The IC structure of claim 1, further comprising:
a first metal line and a second metal line on either side of the optical interconnect in a plane substantially parallel to the device region, wherein the first metal line and the second metal line are substantially parallel to the optical interconnect.

12. The IC structure of claim 1, wherein:
the optical interconnect is a via through at least the third interconnect layer.

13. The IC structure of claim 12, further comprising:
a material comprising a metal on sidewalls of the via.

14. The IC structure of claim 1, wherein:
the optical interconnect is a first optical interconnect, and
the first optical interconnect is between and coupled with a second optical interconnect in the first interconnect layer and a third optical interconnect in the second interconnect layer.

15. The IC structure of claim 1, wherein:
the second dielectric material comprises one or more of:
aluminum nitride, silicon carbide, aluminum scandium nitride, aluminum silicon nitride, and lithium niobate.

16. The IC structure of claim 1, wherein:
the second dielectric material of the optical interconnect surrounds the conductive interconnect.

17. An integrated circuit (IC) structure, comprising:
a device region;
a back-end of line (BEOL) layer over the device region;
a first conductive interconnect and a second conductive interconnect in the BEOL layer; and
a waveguide between the first conductive interconnect and the second conductive interconnect, wherein at least a portion of the waveguide is coplanar with the first conductive interconnect and the second conductive interconnect.

18. The IC structure of claim 17, wherein:
the waveguide is substantially orthogonal to the first conductive interconnect, and
the waveguide comprises a core material comprising a dielectric material and a shielding material surrounding the dielectric material, wherein the shielding material comprises a metal.

19. A method of fabricating an integrated circuit (IC) structure, the method comprising:
providing a preliminary IC structure comprising an interconnect layer;
providing an insulator material over the interconnect layer;
forming an opening in the insulator material;
filling the opening with an optical core material comprising a dielectric material; and
forming a further interconnect layer over the optical core material.

20. The method of claim 19, wherein:
forming the opening comprises forming a trench parallel with the interconnect layer.
